(19) United States
(12) Patent Application Publication
(10) Pub. No.: US 2007/0159192 A1
(43) Pub. Date: Jul. 12, 2007

(54) Probing apparatus

(76) Inventors: Yoshiei Hasegawa, Kawasaki-shi (JP); Hikaru Masuda, Hirosaki-shi (JP); Katsuo Yasuda, Hirosaki-shi (JP); Kenichi Washio, Yokohama-shi (JP); Masashi Hasegawa, Tokyo (JP)

Correspondence Address: BLACK LOWE & GRAHAM, PLLC, 701 FIFTH AVENUE, SUITE 4800, SEATTLE, WA, 98104, US

(21) Appl. No.: 11/650,066

(22) Filed: Jan. 4, 2007

Related U.S. Application Data
(63) Continuation of application No. 11/640,113, filed on Dec. 15, 2006.

(30) Foreign Application Priority Data
Jan. 10, 2006 (JP) JP2006-002177

(51) Int. Cl. G01R 31/02

(52) U.S. Cl. 324/754

(57) ABSTRACT

A probing apparatus comprising: an inspection stage for receiving a flat plate-like device under test with a plurality of electrodes and moving the device under test on the inspection stage in at least three directions, that is, an X direction and a Y direction intersecting each other within a parallel plane to the device under test, and a Z direction intersecting both the directions; a probe card having a plurality of probes and spaced apart from the inspection stage in the Z direction such that the probe tips face the inspection stage; a displacement mechanism for relatively displacing the probe card and the inspection stage for adjustment of parallelism of the device under test on the inspection stage and the probe card; a plurality of measuring instruments respectively for measuring the interval between the inspection stage and the probe card and arranged at intervals in one of the inspection stage and the probe card in the X direction and the Y direction; a control portion for controlling at least the measuring instruments, the inspection stage and the displacement mechanism; and a memory portion for storing the measured interval by each measuring instrument.

### FIELD OF THE INVENTION

This invention relates to a probing device for testing a flat plate-like apparatus under test such as a semiconductor integrated circuit (IC).

### BACKGROUND OF THE INVENTION

A flat plate-like device under test such as a semiconductor wafer with a plurality of integrated circuits formed thereon is to undergo an electrical test as to whether or not each integrated circuit has a prescribed function. The electrical test of this type is generally performed by means of a probing apparatus (testing apparatus) which uses a probe card having a plurality of probes individually corresponding to electrodes of a device under test. Each probe has a tip, i.e., a needle point to be pressed against the corresponding electrode.

In general, a probing apparatus is provided with a positioning member like a positioning pin or stopper and a positioning mechanism such as an inspection stage. The inspection stage includes a mounting table (receiving table) such as a chuck top for receiving a device under test and moves the mounting table, in turn, the device under test on the mounting table, in three directions of X, Y and Z, to angularly rotate the same about a θ-axis extending in the Z direction.

On the other hand, in the probe card, positions of tips are adjusted when manufacturing the probe card, by using a positioning standard of a sample of a device under test, design drawings and the like, so that the height positions of the tips (i.e., Z-coordinate positions) from an imaginary reference plane may fall within an allowable range and that two-dimensional positions (i.e., XY-coordinate positions) of the tips within an XY plane parallel to the device under test may fall within an allowable range with respect to an imaginary reference two-dimensional position (i.e., a two-dimensional position of a corresponding electrode).

The above-mentioned positioning standard includes, in a state that the probe card is mounted on the probing apparatus, a base plate face such as an imaginary plane or the like to be formed by the face of a device under test itself disposed in the probing apparatus and the plural electrodes, as well as a face of each electrode corresponding to the two-dimensional position in the base plate face.

In view of the above, in a state that the probe card and the device under test are attached to the probing apparatus, a probe face such as an imaginary plane formed by a face of the probe card itself and the plural tips and a reference plane formed by a face of the device under test itself and its electrodes become parallel, and the tips of all the probes can be brought into contact with the corresponding electrodes.

However, even in case of such a probing apparatus and probe card, it is difficult to attach the probe card to the probing apparatus so that the positions of the tips relative to the electrodes of the device under test disposed in the probing apparatus may be in the same state as the tip positions after adjustment of positions at the time of manufacture.

Thus, conventionally, in a state that a probe card is attached to a probing apparatus, an imaginary probe face representing the height positions of the tips of the probes provided in the probe card tends to be inclined to a base plate face on the side of the device under test disposed in the probing apparatus.

Where a probe card is attached to a probing apparatus in such an inclined state, three-dimensional position (Z position (height position) and XY positions (two-dimensional position)) of the tips relative to the electrodes of an actual device under test disposed in the probing apparatus do not become the same as the positions of the tips after adjustment of positions at the time of manufacture. It causes a state that tips of some probes are not accurately brought into contact with the electrodes, thereby failing in an accurate test.

One of positioning techniques to solve the foregoing problem is described in the following patent document 1, wherein, after a probe card is attached to a probing apparatus, three-dimensional positions of the tips of arbitrary four probes and three-dimensional positions of four electrodes of a device under test arranged in the probing apparatus are determined, and the device under test is displaced relative to the probe card by using the determined three-dimensional positions (Patent Document 1).

Patent Document 1

Japanese Patent No. 3193958

In the conventional probing apparatus, a mounting table (receiving table) such as a chuck top for receiving a device under test is attached to an inspection stage for moving the mounting table in the three directions of X, Y and Z by means of a ball joint.

The foregoing prior art using such a probing apparatus obtains a probe face formed by four tips and a base plate face formed by four electrodes individually corresponding to the four tips, relatively displaces the device under test and the probe card along the spherical face of the ball joint so that the probe face and the base plate face may become parallel, and thereafter, relatively moves the device under test and the probe card two-dimensionally so that four probe tips may be accurately brought into contact with the corresponding electrodes.

On the other hand, when an electrical test is conducted, applying heat to a device under test, each part of the probing apparatus is deformed due to heat, and the probe face and the base plate face do not become parallel. In such a case, it is desirable to perform the above-mentioned adjustment of positions, particularly adjustment of parallelism of the probe face and the base plate face frequently during testing plural devices under test.

Conventionally, however, the above-mentioned adjustment of positions is performed only when a probe card is attached to a probing apparatus, and not during testing of plural devices under test.

Also, if such adjustment of positions is going to be performed by the foregoing conventional art during testing of plural devices under test, a probe face and a base plate face should be obtained newly every time the positions are adjusted, thereby complicating the adjustment of parallelism.

Especially, in a probing apparatus using a probe card with 10000 or more probes like a probe card for testing multiple integrated circuits formed on one semiconductor wafer, it takes much time and labor for an adjustment of parallelism.

### SUMMARY OF THE INVENTION

An object of the present invention is to facilitate adjustment of parallelism of a probe card during testing.

The probing apparatus according to the present invention comprises: an inspection stage for receiving a flat plate-like device under test having plural electrodes and for moving the device under test on the inspection stage in at least three directions of X, Y intersecting each other within a plane parallel to the device under test and a Z direction intersecting both the directions; a probe card with plural probes whose tips are supported at intervals from the inspection stage in the Z direction so as to face the inspection stage; a displacing mechanism for relatively displacing the probe card and the inspection stage for adjusting the parallelism of the device under test on the inspection stage and the probe card; plural measuring instruments each for measuring an interval between the inspection stage and the probe card and arranged in either one of the inspection stage and the probe card at intervals in the X direction and the Y direction; a control portion for controlling at least the measuring instruments, the inspection stage and the displacing mechanism; and a memory portion for storing the intervals measured by the respective measuring instruments.

The memory portion can store each of the data of the measured values in a state that the probe face of the probe card and the base plate face of the device under test are parallel.

The probe face can be made an imaginary plane representing the height position of the probe tips.

The base plate face can be the surface of the device under test or an imaginary plane formed by an electrode group provided on the surface.

The interval between the probe face and the base plate face is measured before starting a test in a state that the faces are parallel such as when the probe card is mounted on the probing apparatus, and the results of the measurement are pre-stored in the memory portion.

When the adjustment of parallelism of the probe face and the base plate face is performed during testing, the interval is measured by each measuring instrument, and the control portion, comparing the measured values and the pre-stored values, controls the displacing mechanism so that both values may coincide. By this, the parallelism of the probe face and the base plate face is adjusted.

It is not necessary, therefore, to obtain the probe face and the base plate face at the time of adjusting parallelism during testing, so that a complicated operation process and the like are no longer necessary, thereby facilitating the adjustment of parallelism during testing.

Each measuring instrument can include a laser length measuring instrument which uses a laser beam.

The probing apparatus can further comprise a plurality of targets individually corresponding to the measuring instruments and to be used for measuring the intervals by the corresponding measuring instrument and arranged on the other of the inspection stage and the probe card.

Another probing apparatus according to the present invention comprises: an inspection stage for receiving a flat plate-like device under test having plural electrodes and for moving the device under test on the stage at least in the X direction and the Y direction intersecting each other within a plane parallel to the device under test and in the Z direction interesting both the directions, and a probe card having a base plate and plural probes provided on one face of the base plate, the probes being arranged at intervals from the inspection stage in the Z direction such that the probe tips face the inspection stage; and a memory storing information on at least the probes of the device under test is disposed on the base plate of the probe card.

Still another probing apparatus according to the present invention further comprises a card table spaced apart from the inspection stage in the Z direction and having a hole penetrating in its thickness direction and supporting the probe card. The memory portion has a plurality of terminals for recording and reading information, and the probe card has a plurality of wirings connected to the terminals of the memory. The card table can have a plurality of first contact pins in electrical contact with the wirings of the probe card disposed therein, and a plurality of second contact pins connected to the first contact pins.

Yet another probing apparatus further comprises: a stage table supporting the inspection stage; a card table spaced apart from the inspection stage in the Z direction, the card table having a through hole in its thickness direction and supporting the probe card; and a displacing mechanism for relatively displacing the probe card and the inspection stage to adjust the parallelism of the device under test received on the inspection stage and the probe card. The memory has plural terminals for recording and reading information. The probe card has a first infrared communication apparatus connected to a terminal of the memory. The card table includes a support member supported on the stage table by the displacing mechanism, and a ring-like card holder supported on the stage table so as to penetrate the support member in the Z-direction and supporting the probe card so that the probe tips may face the inspection stage. The card holder has a space to permit the infrared ray transmitted from the first infrared communication apparatus to pass. The support member has a second infrared communication apparatus for receiving through the space the infrared ray transmitted from the first infrared communication apparatus.

The memory can include a data carrier capable of reading the information stored therein by use of an electromagnetic wave, or a removable disk removably disposed on the base plate.

### BRIEF DESCRIPTION OF THE DRAWINGS

FIG. 1 is a block diagram showing one embodiment of the probing apparatus according to the present invention.

FIG. 2 is a plan view of the probing apparatus shown in FIG. 1.

FIG. 3 is a plan view showing one embodiment of a device under test.

FIG. 4 are views for explaining a physical relation of probes relative to electrodes of the device under test, of which A is a plan view and B a view seeing A from left.

FIG. 5 is a view showing a physical relation between the electrodes of the device under test and probe tips for explaining the principle of adjustment of a two-dimensional position.

FIG. 6 is a bottom view showing one embodiment of the probe card.

FIG. 7 is a plan view showing one embodiment of a receiving table.

FIG. 8 is a section showing one embodiment of a method of taking out data stored in a memory.

FIG. 9 is a view for explaining the principle of adjusting parallelism.

FIG. 10 is a flow chart for explaining motion of the probing apparatus shown in FIG. 1.

FIG. 11 is a view showing another embodiment of the probing apparatus according to the present invention.

FIG. 12 is a section showing another embodiment of a method to take out the data stored in the memory.

FIG. 13 is a plan view showing one embodiment of a probe card using a data carrier as a memory.

FIG. 14 is a plan view showing one embodiment of a probe card using a removable disk as a memory.

FIG. 15 is a section showing another embodiment of a displacing mechanism.

### DETAILED DESCRIPTION OF EMBODIMENTS

Regarding terms

In the present invention, the base plate face means a face of a device under test itself or an imaginary plane formed by plural electrodes provided in the device under test; the probe face means a face of a wiring base plate to be described later and a face of a probe base plate, or an imaginary plane formed by the tips of plural probes provided in the probe card.

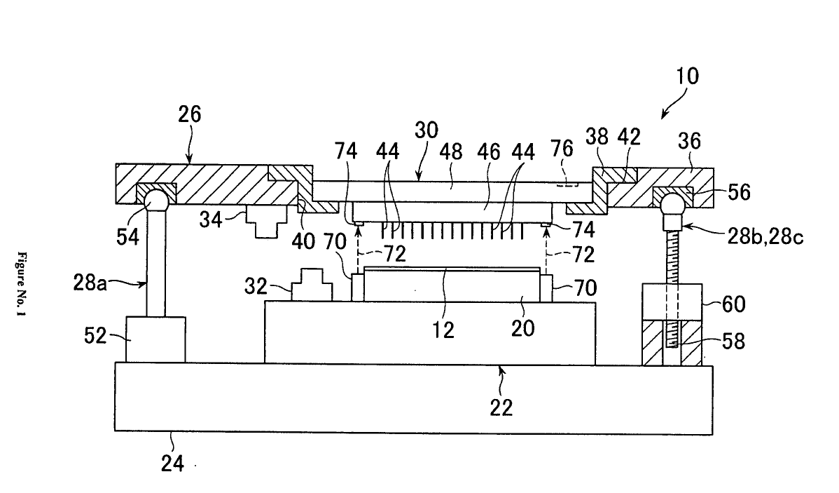

Also, in the present invention, in FIG. 1, the rightward and leftward direction is called an X direction or a lateral direction, and a perpendicular direction thereto is called a Y direction or a longitudinal direction, and an upward and downward direction is called a Z direction or a vertical direction. However, those directions differ, depending on attitudes of a device under test to be disposed in the probing apparatus.

Accordingly, the above-mentioned directions may be determined, depending on an actual probing apparatus, such that the X direction and Y direction come within any one of a horizontal plane, an inclined plane inclined to the horizontal plane and a vertical plane vertical to the horizontal plane, or to become a combination of those planes.

### Embodiments

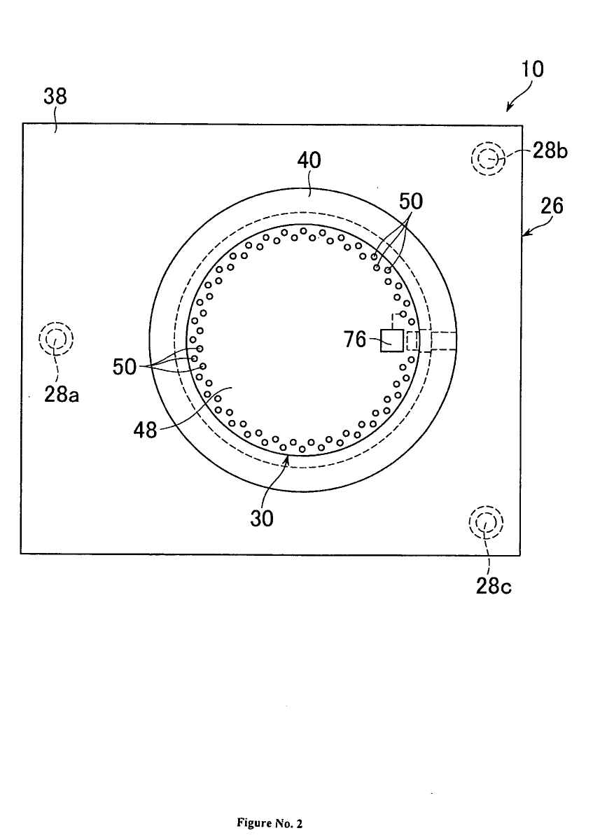

Referring to FIGS. 1 and 2, an inspection apparatus, i.e., a probing apparatus 10 is used for electrical test of a flat-plate like device under test 12.

Device Under Test

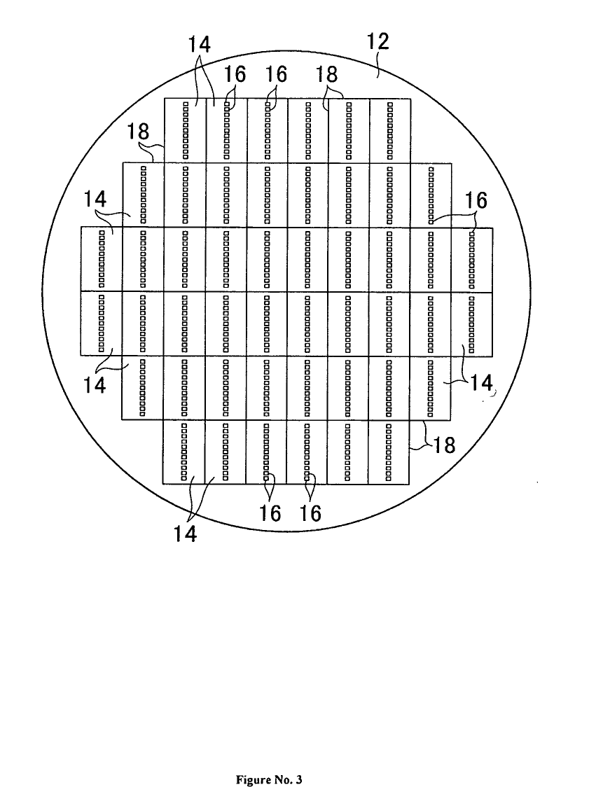

The device under test 12 is, as shown in FIG. 3, a disk-like semiconductor wafer with multiple IC chip regions (regions to be tested) 14 arranged in a matrix state, and a plurality of electrodes 16 are aligned in a row in each IC chip region 14. Respective electrodes 16 of the IC chip regions 14 adjoining in the Y direction are aligned in a row. The IC chip regions 14 adjoining in the X and Y directions are marked off by scribed lines 18.

In the following, to simplify the explanation and facilitate understanding, explanation about the probing apparatus 10 is directed to a case where all the IC chip regions 14 of the device under test 12 are simultaneously tested only once. The probing apparatus 10, however, may be of a type to test all the IC chip regions 14 of the device under test 12 in several times.

Each electrode 16, in the following explanation, is a pad electrode with a rectangular planar shape. It may, however, have another planar shape such as circular, elliptical and the like. Also, each electrode 16 is not necessarily a plate-like electrode but may have another shape such as convex like a hemispherical bump electrode.

Probing Apparatus

Again referring to FIGS. 1 and 2, the probing apparatus 10 comprises: an inspection stage 22 provided with a receiving table 20 like a chuck top for adsorbing the device under test 12 by vacuum force; a plate-like stage table 24 for supporting the inspection stage 22; a plate-like card table 26 spaced apart upward from the stage table 24; three connection mechanisms 28a, 28b and 28c for connecting the stage table 24 and the card table 26 so as to have the card table 26 supported on the stage table 24; a probe card (PC) 30 disposed on the card table 26 so as to oppose the receiving table 20; a lower camera 32 disposed on the inspection stage 22 movably in the X and Y directions; and an upper camera 34 disposed on the card table 26.

The receiving table 20 is ring-shaped or disk-shaped and has a flat circular adsorption face (the top face in the figure) for receiving the device under test 12 horizontally, and further has a plurality of adsorption grooves for releasably adsorbing the device under test 12 on the adsorption face. The adsorption grooves are connected to a vacuum apparatus (not shown).

The inspection stage 22 includes, though not illustrated, not only the receiving table 20 but also a three-dimensional drive mechanism for moving the receiving table 20 three-dimensionally in the three directions of X, Y and Z, and a θ drive mechanism for angularly rotating the receiving table 20 about a θ-axis extending in the Z direction. These drive mechanisms are equipped on the stage table 24 disposed within a housing (not shown) of the probing apparatus 10.

The stage table 24 is disposed horizontally within a housing (not shown) of the probing apparatus 10. The inspection stage 22 has one of the three-dimensional drive mechanism and the 0 drive mechanism disposed on the stage table 24 such that one of the three-dimensional drive mechanism and the θ drive mechanism supports the other. The receiving table 20 is supported on the other of the three-dimensional drive mechanism and the θ drive mechanism.

The card table 26 includes a plate-like support member 36 supported on the stage table 24 by means of the connection mechanisms 28a, 28b and 28c, and a ring-like card holder 38 supported on the support member in a state of penetrating the support member 36 in the Z direction.

The support member 36 has, besides a circular hole 40 penetrating the support member vertically, an upward stage portion 42 extending in a circular shape along the upper periphery of the hole 40 around the hole 40.

In the card holder 38, the flange-like upper outer periphery extends outward in the radial direction, the outer periphery is received on an upward stage portion 42 of the support member 36, an intermediate portion is fitted into the hole 40 so as to extend downward from the inside of the upper outer peripheral portion, and formed in a ring-like shape with a member having a Z-like section so that a flange-shaped lower inner periphery may extend inward in the radial-direction from the lower end of the intermediate portion to receive the probe card 30 in the inner periphery.

The card holder 38 is mounted on the card table 26 by means of a plurality of attaching screws and positioning pins (both not shown) penetrating the upper outer periphery thereof in the thickness direction and screwed into the support member 36.

The probe card 30 has a plurality of probes 44 individually corresponding to the electrodes 16 of the device under test 12, and a probe base plate 46 with the probes attached to the bottom face thereof, said probe base plate 46 being attached to the bottom face of a wiring base plate 48 which has a circular planar shape.

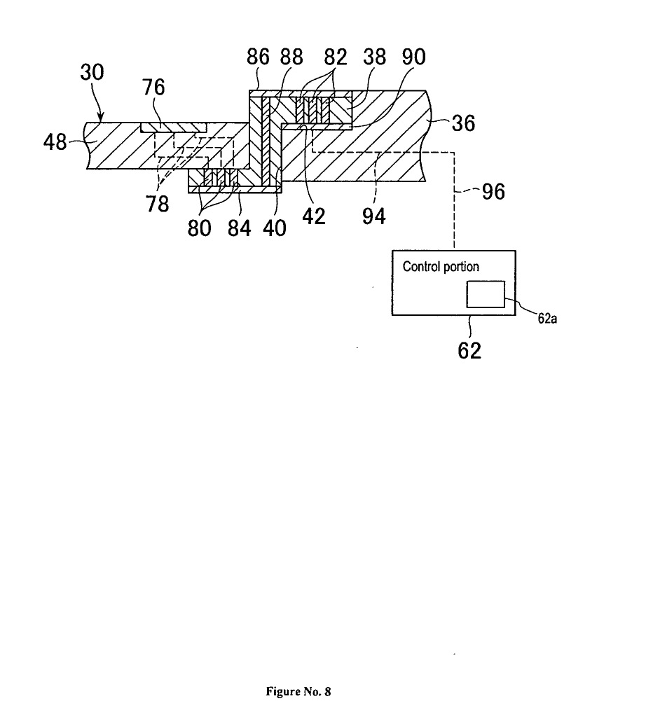

Respective probes 44 are electrically connected to the wiring base plate 48 through the wiring provided on the probe base plate 46 and further electrically connected to a tester land 50 provided on the wiring base plate 48 by the wiring of the tester lands 50 provided in the wiring base plate 48. Each tester land 50 is electrically connected to a tester (see FIG. 8) which receives and transmits electrical signals to the device under test 12.

The probe card 30 is attached to the card holder 38 at the lower outer periphery of the wiring base plate 48 by means of a plurality of attaching screws and the positioning pins (both not shown) such that the tips of the probes 44 are directed to the inspection stage 22.

The probes 44 are arranged on the probe base plate 46 such that their tips (i.e., needle points) are aligned in the same manner as the aligned state of the corresponding electrodes 16. Thus, the tips of the probes 44 corresponding to the electrodes 16 in the same IC chip region 14 are aligned in a row, and the tips of the probes 44 corresponding to the electrodes 16 of the IC chip regions 14 adjoining in the Y direction are also aligned in a row.

One connection mechanism 28a is a fixed support connected at one end portion to one of the stage table 24 and the card table 26 by means of a bracket 52 so as to extend in the Z direction, and at the other end, connected displaceably to the other of the stage table 24 and the card table 26.

The remaining connection mechanisms 28b and 28c are provided at one end portion with a movable body 58 connected to one of the stage table 24 and the card table 26 by means of a ball joint 56 so as to extend in the Z direction and to be displaceably, and a drive mechanism 60 disposed on the stage table 24 and for displacing the movable body 58 in the Z direction.

In the illustrated example, all of the connection mechanisms 28a, 28b and 28c are connected to the card table 26 by means of the ball joint 54 or 56.

The movable body 58 is a ball screw, and the drive mechanism 60 is a hollow motor with a female screw portion for screwing the movable body 58 together in a rotation axis portion The connection mechanisms 28a, 28b and 28c, therefore, move the movable body 58 in the Z direction by normally and reversely rotating the drive mechanism 60 to displace the card table 26 relative to the stage table 24, in turn, the inspection stage 22, and act as displacement mechanisms for tilting the card table 26 to the stage table 24 and the inspection stage 22.

The upper and lower cameras 34 and 32 are video cameras having a function of automatic focusing.

The lower camera 32 is set on the inspection stage 22 to face upward so as to image the tips of the probes 44, and are moved two-dimensionally in the X and Y directions by the inspection stage 22 to image the tips of the probes 44.

The upper camera 34 is attached to the bottom face of the card table 26 to face downward so as to image the electrodes 16 of the device under test 12 disposed on the inspection stage 22. The upper camera 34, by moving the receiving table 20 two-dimensionally in the X and Y directions, images the electrodes 16 of the device under test 12. The upper camera 34 may be attached to the probe card 30 or the card holder 38

The moving face of the lower camera 32 by the inspection stage 22 acts as an imaginary first reference plane set in the probing apparatus 10 for the tips. An imaginary moving face of the upper camera 34 accompanying the movement of the receiving table 20 by the inspection stage 22 acts as an imaginary second reference plane set in the probing apparatus 10 for the electrodes 16.

An output signal of the lower camera 32 is used to obtain the tip height positions which are the height positions of the electrodes 16 from the first reference plane in a prober control portion 62 (see FIG. 8) for controlling the probing apparatus 10, and besides, to obtain the probe face of the probe card 30 in a state of being attached to the probing apparatus 10 from some of the height positions.

The output signal of the upper camera 34 is used to obtain in the prober control portion 62 the electrode height positions which are the height positions of the electrodes 16 from the second reference plane, and besides, to obtain the electrode face of the device under test 12 as the base plate face in a state that the probing apparatus 10 is disposed.

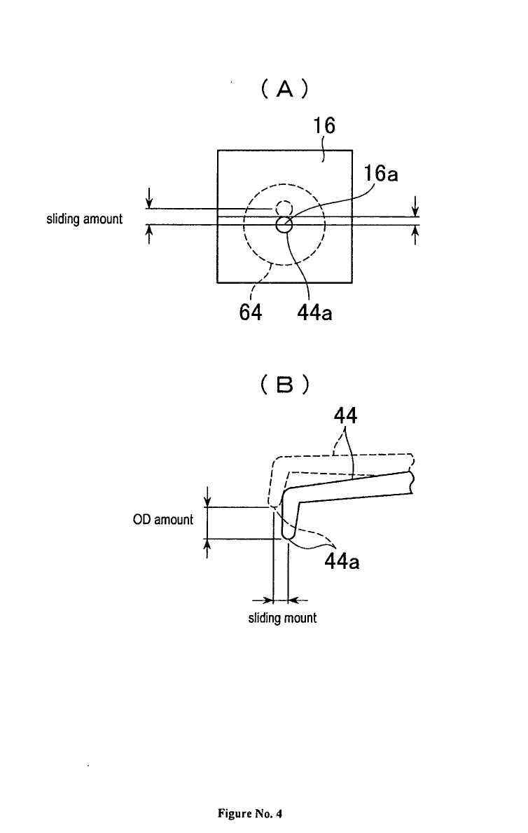

In the probe card 30, as shown in FIGS. 4A and B, when a predetermined amount of an overdrive OD in the Z direction acts on the probes 44 with the tip 44a of each probe 44 brought into contact with a set position 16a of the corresponding electrode 16, the tips 44a are produced so as to slide by a predetermined amount relative to the electrodes 16 within the X and Y planes.

The set position 16a is a target position for the tips 44a to contact, and is set by taking into account the sliding amount of the tips 44a relative to the electrodes 16 when the overdrive is applied.

It is difficult, however, to produce the probe card 30 such that each tip 44a comes into contact accurately with the set position 16a of the corresponding electrode 16. Therefore, a permitted range 64 is determined the position for each tip 44a to come into contact with the corresponding electrode 16. As a matter of course, allowable ranges are determined for the above-mentioned overdrive (OD) amount of sliding amount.

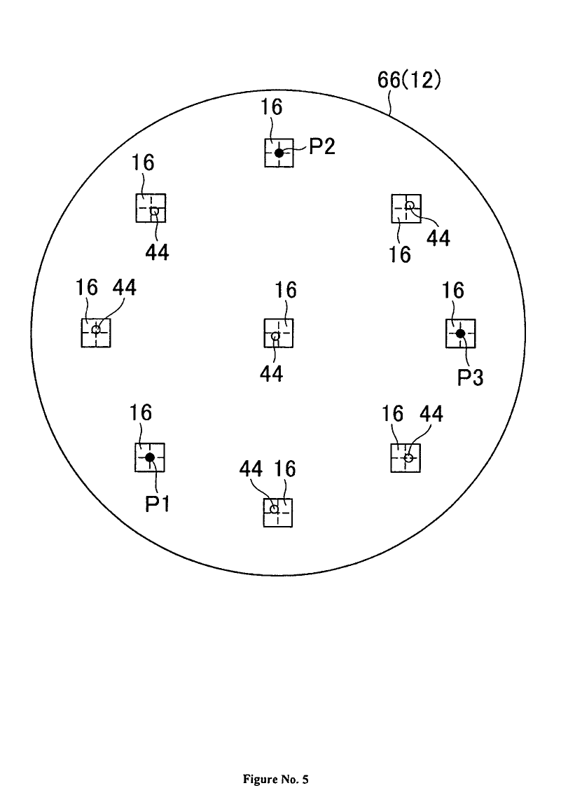

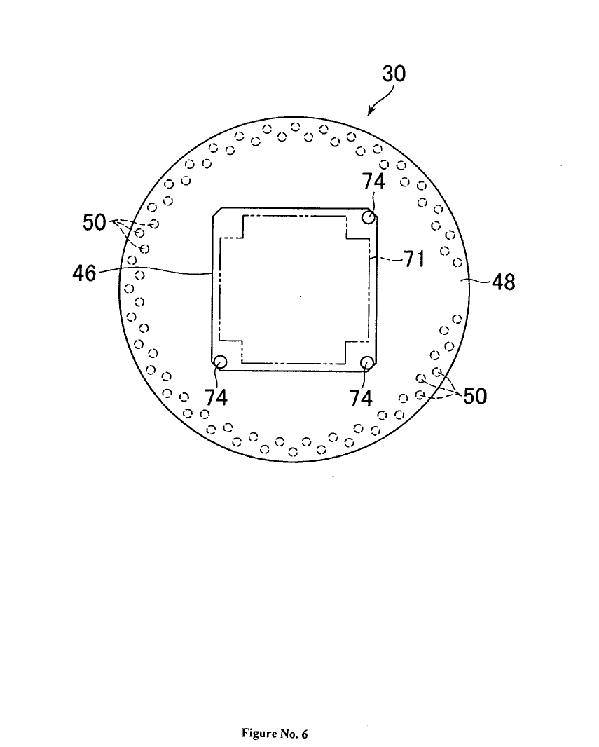

In view of the above, when producing, the probe card 30 is adjusted its tip positions by using a position standard 66 (see FIG. 5) such as a sample of the device under test 12 so that the probe face may become parallel to the reference plane and that the tip 44a of each probe 44 may fall within the allowable range 64. FIG. 6 is illustrated, with many of the electrodes and many of the tips 44a omitted, to facilitate understanding.

The probe card 30 with its tip positions adjusted as mentioned above is attached to the probing apparatus 10 and is adjusted such that the positions of the tips 44a relative to the corresponding electrodes 16 fall within the allowable range 64 in that state.

As mentioned above, the probe card 30 is attached to the card holder 38 with a plurality of screw members and positioning pins, and the card holder 38 is attached to the card table 26 with a plurality of screw members and positioning pins.

As a result, a pre-aligned direction (e.g., the alignment direction of the tips 44a) in the probing apparatus 10 such that the predetermined direction for the probe card 30) in the probe card 30 coincides with the predetermined direction for the probing apparatus 10 and that the two-dimensional position of each tip 44a coincides with the predetermined two-dimensional position for the probing apparatus 10.

However, even if the probe card 30 is pre-aligned as mentioned above, the probe face of the probe card 30 is not always parallel to the reference plane of the device under test 12 disposed in the probing apparatus 10, and the position of each tip 44a relative to the set position 16a of the electrode 16 is not always within the allowable range 64.

Therefore, positioning is carried out in such a manner as mentioned later.

As shown in FIGS. 1, 6 and 7, the probing apparatus 10 comprises a plurality of measuring instruments 70 each for measuring the distance between the inspection stage 22 and the probe card 30. Those measuring instruments 70 are arranged at intervals in the X direction and Y direction on either one of the inspection stage 22 and the probe card 30. Each measuring instrument 70 may be a laser length measuring instrument which uses a laser beam 72.

On the other hand, in the other of the inspection stage 22 and the probe card 30, targets 74 are disposed at radiation positions by each measuring instrument 70. Each target 74 may be a reflecting mirror.

In the illustration, three measuring instruments 70 located at the vertexes of a triangle, with a laser beam window and an entrance directed upward, are arranged on the inspection stage 22 at intervals around the mounting table 20. Also, the targets 74 are attached to the bottom face of the probe base plate 46 to face downward.

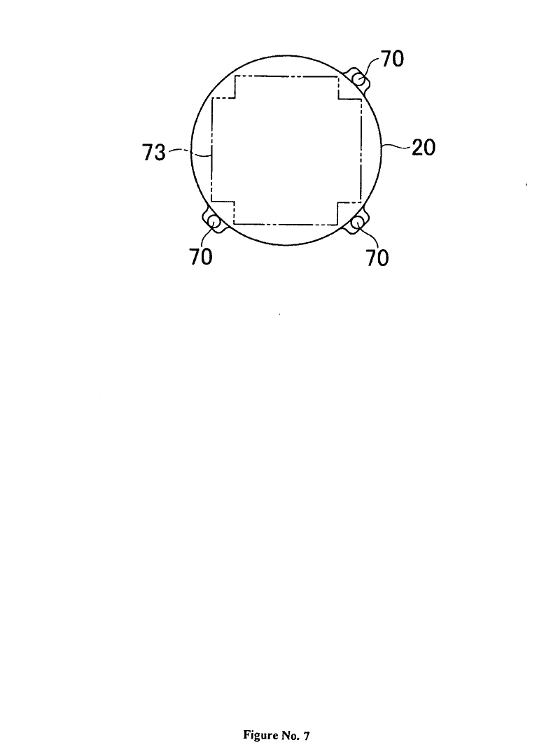

In FIG. 6, the region 71 indicated by a two-dot chain line represents an arrangement region of the probes 44. Also, in FIG. 7, the region 73 indicated by a two-dot chain line represents a formation region of the IC chip region 14.

As shown in FIG. 8, the probe card 30 has a memory 76 disposed on the wiring base plate 48. The memory 76 stores probe card information including information on the probes 44.

In the illustration, the memory 76 is an IC memory with plural terminals for writing and reading information. Thus, the wiring base plate 48 has a plurality of wirings 78 connected to the terminals of the memory 76.

The card holder 38 has a plurality of first contact pins 80 electrically connected at one ends to the wirings of the probe card 30 arranged thereon at the lower outer periphery as well as a plurality of second contact pins 82 electrically connected at one ends to the other ends of the first contact pins 80 at the upper outer periphery.

The card holder 38 further has a first and a second connection base plates 84 and 86 respectively having a plurality of wirings on the bottom face of the lower periphery and the top face of the upper outer periphery as well as a plurality of connection pins 88 in the intermediate portion.

Respective wirings of the first connection base plate 84 are electrically connected to the other ends of their corresponding contact pins 80 and the one ends of their corresponding connection pins 88. Respective wirings of the second connection base plate 86 are electrically connected to the other ends of their corresponding connection pins 88 and the one ends of their corresponding second contact pins 82.

The support member 36 has a third connection base plate 90 having a plurality of wirings respectively electrically connected to the other ends of the second contact pins 82 in the upward stage portion 42. Each wiring of the third connection base plate 90 is electrically connected to the prober control portion 62 through the wiring 94 provided in the support member 36 and a cable 96 electrically connected thereto.

Positioning Method

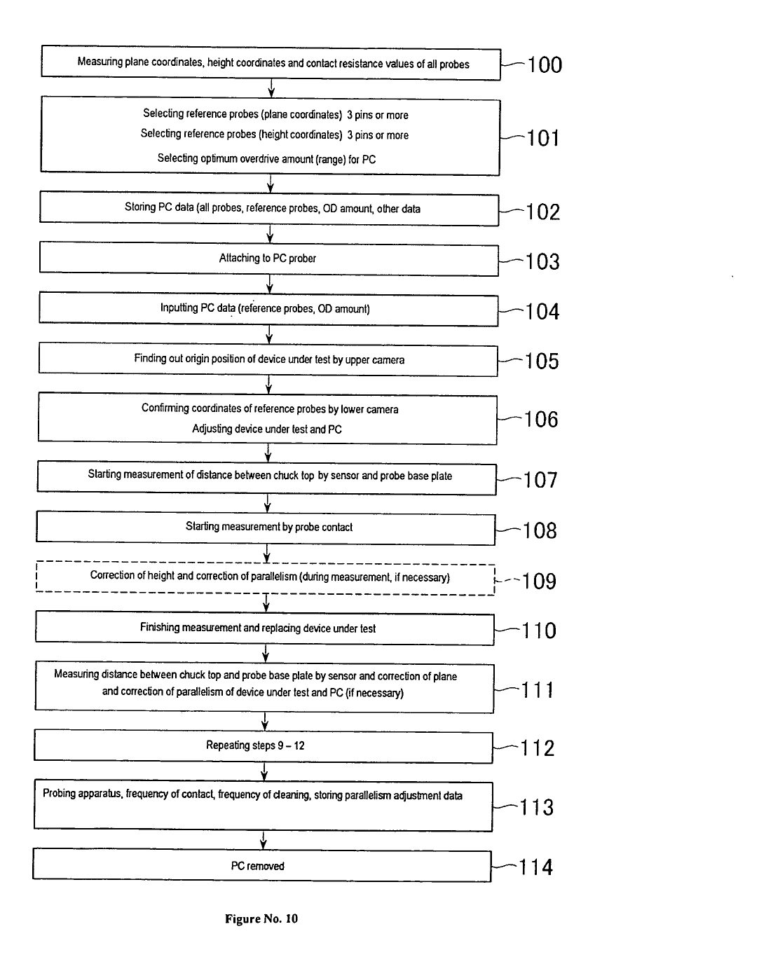

In the following, referring to FIG. 1 through FIG. 10, a method of positioning the tips 44a of the probes 44 and the electrodes 16 of the device under test 12 is explained with respect to one embodiment thereof. In FIG. 10, the term “probe card” is shown by a symbol “PC.”

Determining Probe Information

Before the probe card 30 is attached to the probing apparatus 10, particularly at the time of production, the following steps are previously carried out to determine reference data.

1. The plane coordinates of all the probes 44 (two-dimensional positions of the tips) after their tip positions are adjusted by using the position standards 66 (see FIG. 5) as mentioned above, the height coordinates (height positions of the tips) and contact resistances (step 100 in FIG. 10) are measured.

2. Secondly, at least three probes located at the set positions 16a are selected as first reference probes P1, P2 and P3 (see FIG. 5) for determining the two-dimensional tip positions, and the two-dimensional tip positions of those selected first reference probes P1, P2 and P3 are determined as two-dimensional reference tip positions (step 101 in FIG. 10).

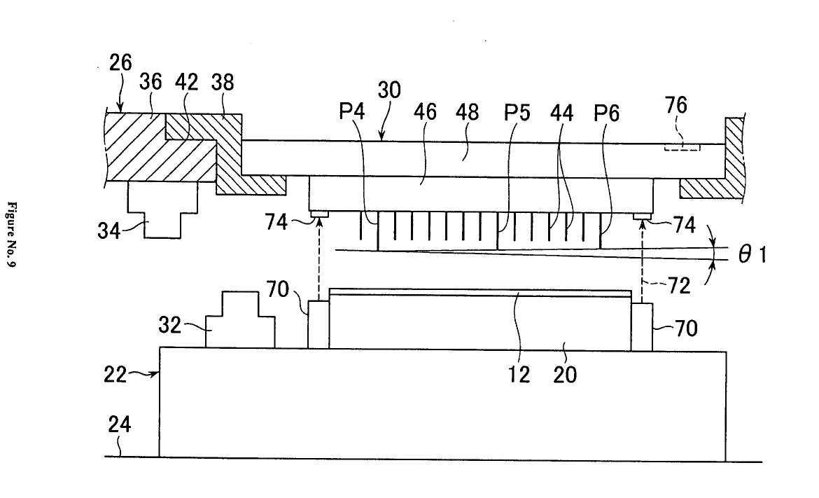

3. Thirdly, at least three probes of the same tip height position are selected as second reference probes P4, P5 and P6 (see FIG. 9) for determining a tip height reference position, and the tip height position of the selected second reference probes P4, P5 and P6 as the tip height reference position (step 101 in FIG. 10).

From the foregoing tip height reference position, an imaginary plane formed by the tips 44a of the second reference probes P4, Pt and P6 can be obtained as a reference probe plane.

4. Fourthly, an optimum overdrive amount (allowable range) for the probe card 30 is selected, and the selected overdrive amount is determined as the optimum overdrive amount (OD amount) (step 101 in FIG. 10).

Thereafter, various pieces of information on the probe card 30 are stored in the memory 76 (step 102 in FIG. 10).

These pieces of information include another probe card information including the two-dimensional tip positions of the first reference probes P1, P2 and P3, the tip height positions of the second reference probes P4, P5 and P6, the optimum overdrive amount (OD amount) and the probes.

The two-dimensional tip positions and the tip height positions are written as the two-dimensional tip reference positions and tip height reference positions respectively in the memory 76 for each reference probe.

The optimum overdrive amount (OD amount) and another probe card information including the information on the probes are written in the memory 76. The two-dimensional tip reference positions, tip height reference positions and probe Nos. are used later as the probe information.

The two-dimensional tip reference positions are determined as the X and Y coordinate positions of the tips in an imaginary three-dimensional coordinate system of XYZ preset in the probe card 30. The two-dimensional tip reference positions are determined as the X, Y coordinate positions in the imaginary three-dimensional coordinate system of XYZ preset in the probe card. Such two dimensional tip reference positions may be XY coordinate positions of the electrodes corresponding to the reference probes P1, P2 and P3, or when the XY coordinate positions are specified by probe Nos., may be the probe Nos. themselves.

The tip height reference position is determined as Z-coordinate values in the three-dimensional coordinate system (e.g., the height position from a reference plane such as the plane of the position standard 66). The position standard 66 may be an imaginary position of the device under test relative to the probe card 30 when the device under test 12 and the probe card 30 are arranged in the probing apparatus 10.

The two-dimensional tip reference positions and the tip height reference position may be used, in place of newly determining, for determining the two-dimensional tip position and the tip height position of each tip 44a when adjusting the tip position by using the position standard 66, and the corresponding values at that time may be used as the two-dimensional tip reference position and the tip height reference position.

Where the probe card 30 has a plurality of probes 44, there often exist, when adjusting the tip positions, a plurality of probes located in the set positions 16a of imaginary corresponding electrodes 16 where the tips are at the position standard 66 as well as a plurality of probes having the same tip height.

Therefore, at the first reference probes P1, P2 and P3 for obtaining the two-dimensional tip reference position, as shown in FIGS. 4 and 5, at least three probes whose tips 44a are located at the set positions 16a of the imaginary corresponding electrodes 16 and at large intervals from each other can be selected. Unless such probes exist, probes whose tips 44a are near the imaginary set positions 16a and at large intervals can be selected.

Also, as the second reference probes P4, P5 and P6 for obtaining the tip height reference position, as shown in FIG. 9, at least three probes having the same or approximately the same tip height positions (e.g., the greatest or the smallest height positions) and at large intervals from one another can be selected. Unless such probes exist, a plurality of probes whose tip height positions are the closest to one another and at large intervals from one another can be selected.

In view of the above, at least one of the first reference probes P1, P2 and P3 may be the same as at least one of the second reference probes P4, P5 and P6.

In FIGS. 5 and 9, the electrodes 16, the probes 44 and differences in their lengths are shown in an enlarged state and many of the probes 44 are omitted for easy understanding of the process to determine the first and second reference probes from P1 to P6.

Attachment of the probe card and input of probe information

When various pieces of information are stored in the memory 76, the probe card 30 is accurately attached to the probing apparatus 10 by use of the positioning pins or stoppers as mentioned above (step 103 in FIG. 10), and the two-dimensional tip reference position and the tip height reference position stored in step 102 are read out in the control portion 62 of the probing apparatus 10 (step 104 in FIG. 10).

Finding Out the Origin (Aligning Two-Dimensional Coordinates

After the above steps 103 and 104, by use of the scribe lines 18 and IC patterns marking off the adjoining IC chip regions 14 of the device under test 12 as well as the upper camera 34 for imaging them, finding out of the position of the origin of the device under test 12 relative to the probing apparatus 10 (i.e., alignment of the two-dimensional coordinates) is performed (step 105 in FIG. 10).

The foregoing finding out of the origin is a step for making the XY coordinate of the device under test 12 coincide with the imaginary XY coordinate set in the probing apparatus 10, and can be carried out as follows. The three-dimensional coordinate of the probing apparatus 10 can be obtained by means of software in the control portion 62 (see FIG. 8).

First, while imaging the device under test 12 with the upper camera 34, the receiving table 20, in turn, the device under test 12 is moved two-dimensionally within the XY coordinate of the probing apparatus 10 by the inspection stage 22, and an output signal of the upper camera 34 at that time is temporarily stored in the memory portion 62a (see FIG. 8) as an image signal.

Next, using the stored image signal, differences in position and angle between the imaged scribe lines 18 (see FIG. 3) and the XY coordinate of the probing apparatus 10 are obtained in the control portion 62.

Then, making the controller of the probing apparatus 10 control the drive unit of the inspection stage 22 to move the receiving table 20 two-dimensionally within the XY coordinate of the probing apparatus 10 by the inspection stage 22 so as to correct the obtained differences in position and angle and angularly rotate about the θ axis.

Instead of the foregoing, it is possible to correct the differences in position and angle by changing the coordinate itself set in the control portion 62 of the probing apparatus 10 software-wise.

By finding out the origin or making two-dimensional coordinates coincide, the XY coordinate of the device under test 12 is made to coincide with the XY coordinate of the probing apparatus 10.

Confirmation of the tip height positions as well as adjustment of parallelism as well as confirmation and adjustment of the two-dimensional tip positions]

After finding out the position of the origin, adjustment of the parallelism as well as confirmation and adjustment of the two-dimensional tip positions are made (step 106 in FIG. 10).

The confirmation of the foregoing tip height positions are made while imaging the tip 44a of each probe 44 of the probe card 30 by the lower camera 32, by moving the lower camera 32 two-dimensionally within the XY coordinate of the probing apparatus 10 by the inspection stage 22, and temporarily storing the output signal of the lower camera 32 at that time in the memory portion 62a of the control portion 62 (see FIG. 8).

Concrete values of the tip height positions may be made the focus position of the lower camera 32 when the tips 44a are imaged by the lower camera 32.

The above adjustment of the parallelism is made by obtaining in the control portion 62 the imaginary plane (probe face) formed by the tip height positions of the second reference probes P4, P5 and P6 and the imaginary plane (reference probe face) formed by the pre-stored tip height reference position, and adjusting the parallelism of the probe card 30 and the device under test 12 so that an angle 01 (see FIG. 9) between the obtained probe face and reference probe face may become zero.

The second reference probes P4, P5 and P6 can be specified from the inputted probe Nos. By the foregoing parallelism adjustment, the probe face formed by the tip height positions and the reference probe face formed by the tip height reference position are made parallel.

The parallelism adjustment such as mentioned above can be made by obtaining in the control portion 62 the probe face and the reference probe face and obtaining the inclination angle θ1 between the obtained probe face and reference probe face, and tilting the probe card 30 so that the obtained inclination angle θ1 may become zero.

The inclination of the probe card 30 can be made by normally or reversely rotating the hollow motor 60 of the displacing mechanism 28b, 28c in FIG. 1 and tilting the card table 26 to the receiving table 20.

By the foregoing parallelism adjustment, the probe face of the probe card 30 is made parallel to the base plate face of the device under test 12. This is due to determining the probes 44 having the same or substantially the same tip height positions to be the reference probes P4, P5 and P6 for parallelism adjustment.

For the foregoing parallelism adjustment, the probe card 30 may be tilted without obtaining the probe face and the reference probe face so that merely the tip height positions of the reference probes P4, P5 and P6 may coincide with the corresponding tip height reference position.

The foregoing confirmation of the two-dimensional tip positions can be made, while imaging the tip of each probe 44 of the probe card 30 by the lower camera 32, by moving the receiving table 20, in turn, the lower camera 32 by the inspection stage 22 two-dimensionally within the XY coordinate of the probing apparatus 10, and temporarily storing the coordinate position of the lower camera when the lower camera filmed the tips of the first reference probes P1, P2 and P3 in the memory portion 62a of the control portion 62 of the probing apparatus 10.

The first reference probes P1, P2 and P3 can be specified by their probe Nos. The coordinate position of the lower camera 32 can be obtained, for example, from the coordinate position of the inspection stage 22 when the lower camera 32 filmed the tips of the first reference probes P1, P2 and P3. The foregoing confirmation of the two-dimensional tip positions may be made in parallel with step 106 for confirmation of the tip height positions.

The adjustment of the two-dimensional positions is made by moving the receiving table 20, in turn, the device under test 12 two-dimensionally within the XY coordinate relative to the probe card 30 by the inspection stage 22.

By the foregoing adjustment of the two-dimensional positions, the tips 44a of the reference probes P1, P2 and P3 are positioned at the centers of the corresponding electrodes 16. As a result, the tips of the other probes 44 are determined to be within an allowable range relative to the corresponding electrodes 16.

This is because the tips of all the probes are positioned within the allowable range 64 relative to the corresponding electrodes 16 by the adjustment of the tip positions and because the set positions 16a of the electrodes 16 to which the tips 44a correspond (see FIG. 6) or the probes located substantially at the set positions 16a are determined to be the reference probes P1, P2 and P3.

Next, the distance between the receiving table and the probe base plate 46 is measured (step 107 in FIG. 10).

This measurement is conducted by directing the laser beam 72 from the measuring instrument 70 to the target 74 corresponding thereto, and receiving the reflected light from the target 74 at the measuring instrument 70. Each of the measured distances is stored temporarily in the memory portion 62a of the control portion 62.

Then, an electrical test (measurement) of the device under test 12 is conducted (step 108 in FIG. 10).

The electrical test is conducted in an ordinary manner such that the receiving table 20, in turn, the device under test 12 is raised by the inspection stage 22 to electrify the device under test 12 with the electrodes 16 of the device under test 12 brought into contact with the tips of the probes 44, and that the electric signal outputted from the device under test 12 at that time is received by a tester for the tester to judge whether the device under test 12 is good or not.

If necessary, it is possible to conduct correction of the tip heights (height correction) and adjust the parallelism (correction of parallelism) (step 109 in FIG. 10).

The foregoing parallelism correction is conducted by measuring the distance between the receiving table 20 and the probe base plate 46 by each measuring instrument 70, comparing the value at that time and the previously stored value in the memory portion 62a of the control portion 62, and tilting the probe card 30 to the device under test 12 by the displacing mechanism 28b, 28c so that both may coincide. The memory portion 62a is provided within the control portion 62, but it may be provided independently of the control portion 62.

After the electrical test is finished, the device under test 12 is replaced with another (step 110 in FIG. 10). At the time of the replacement, the probes 44 may be cleaned.

Next, the measuring instrument 70 may conduct measurement of the distance between the receiving table 20 and the probe base plate 46, correction of the tip heights (height correction) and adjustment of parallelism (parallelism correction) (step 111 in FIG. 10). This step 111 is made by the same method as step 109.

Thereafter, steps 109 through 111 are repeated for each device under test (step 112 in FIG. 10).

After all the tests are finished, the data of the probing apparatus, the frequency of contacting, the frequency of cleaning, the data for parallelism adjustment and the like are stored in the control portion 62 (step 113 in FIG. 10), and the probe card (PC) 30 is removed (step 114 in FIG. 10).

With the above steps 100 through 114, the electrical test of a plurality of the device under test 12 of the same kind is completed.

Examples of Deformation

The parallelism adjustment of the probe face and the reference probe face may be conducted by using the tip height positions of the reference probes P4, P5 and P6 and the height positions of their corresponding electrodes, in place of using the tip height positions of the reference probes P4, P5 and P6 and the tip height reference positions.

In this case, for example, it is sufficient to displace the probe card 30, while imaging the electrodes 16 of the device under test 12 with the upper camera 34, by obtaining the height positions of the electrodes 16 corresponding to the second reference probes so that the tip height positions from the obtained electrode height positions may become the same, for example, so that the imaginary base plate face formed by the electrode height positions and the probe face formed by the tip height positions of the second reference probes may become parallel.

Likewise, in place of conducting the adjustment of the two-dimensional positions of the tips of the first reference probes by using the two-dimensional tip positions of the reference probes P1, P2 and P3 and the two-dimensional tip reference position, it is possible to do so by using the two-dimensional tip positions of the reference probes P1, P2 and P4 and the two-dimensional positions of the electrodes corresponding thereto.

In this case, it is sufficient to displace the device under test 12 by the inspection stage 22, for example, in such a manner as step 105, by obtaining the two-dimensional positions of the electrodes 16 corresponding to the second reference probes, i.e., the two-dimensional positions of the electrodes while imaging the electrodes 16 of the device under test 12 with the upper camera 34 so that the two-dimensional positions of the second reference probes may coincide with the obtained two-dimensional positions of the electrodes.

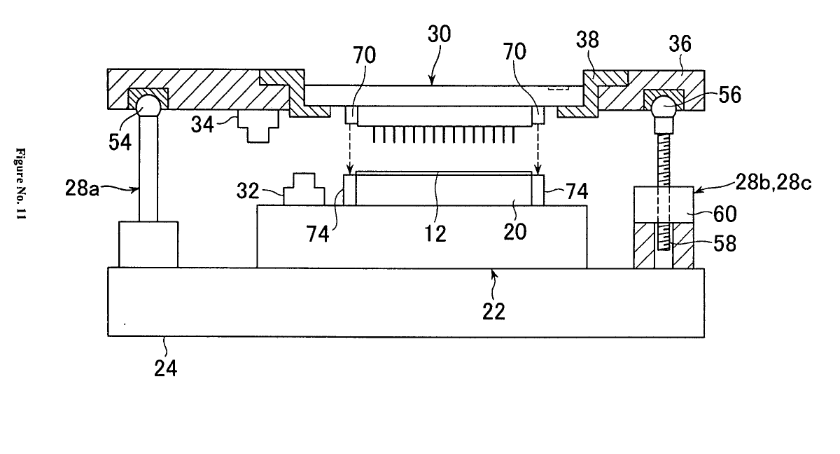

As shown in FIG. 11, the measuring instruments 70 may be attached to the probe card 30, and the targets 74 may be attached to the inspection stage 22.

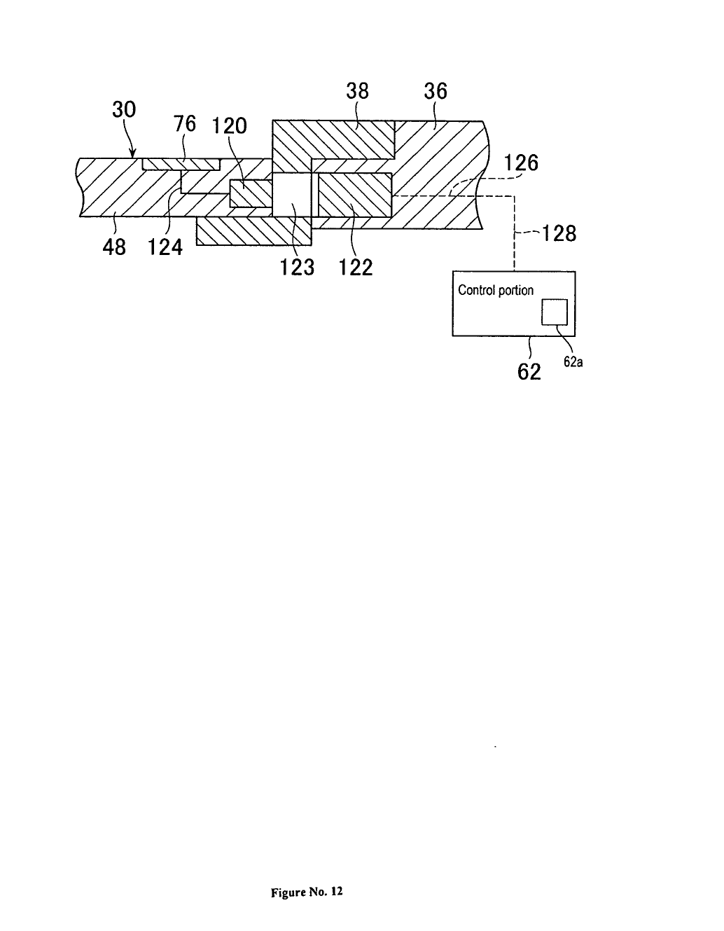

As shown in FIG. 12, the communication of the data stored in the memory 76 may be conducted by means of two infrared communication apparatus 120 and 122.

One infrared communication apparatus 120 is disposed in the probe card 30 and connected to the terminal of the memory 76 by the wiring 124. The other infrared communication apparatus 122 is disposed in the support member 36 of the card table 26 and connected to the control portion 62 by the wiring 126 and cable 128.

The card holder 38 has a space 123 which permits the infrared transmitted from the first infrared communication apparatus 120 to pass, and the support member 36 has a space which permits the infrared transmitted from the infrared communication apparatus 120 to enter the second infrared apparatus 122.

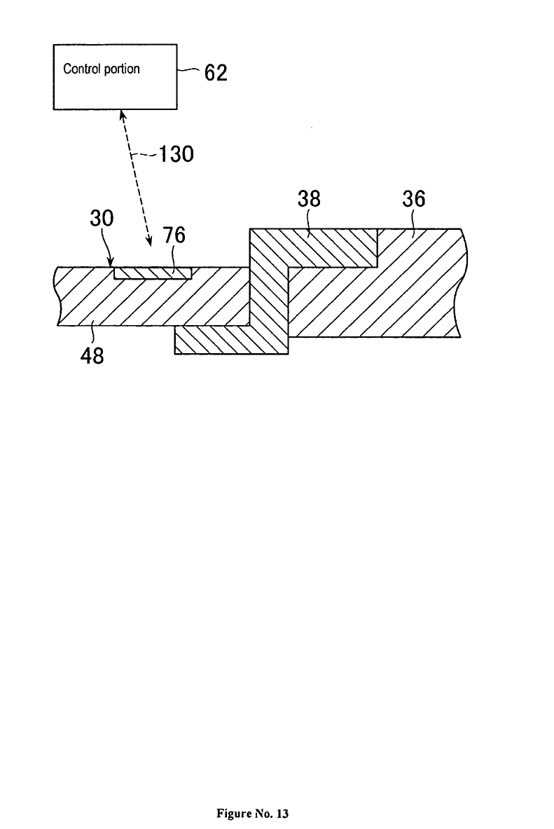

In place of the above, as shown in FIG. 13, the memory 76 can include a data carrier capable of reading the stored information by using an electromagnetic wave. In this case, transfer of the information within the memory 76 is made by using a high-frequency wave 130.

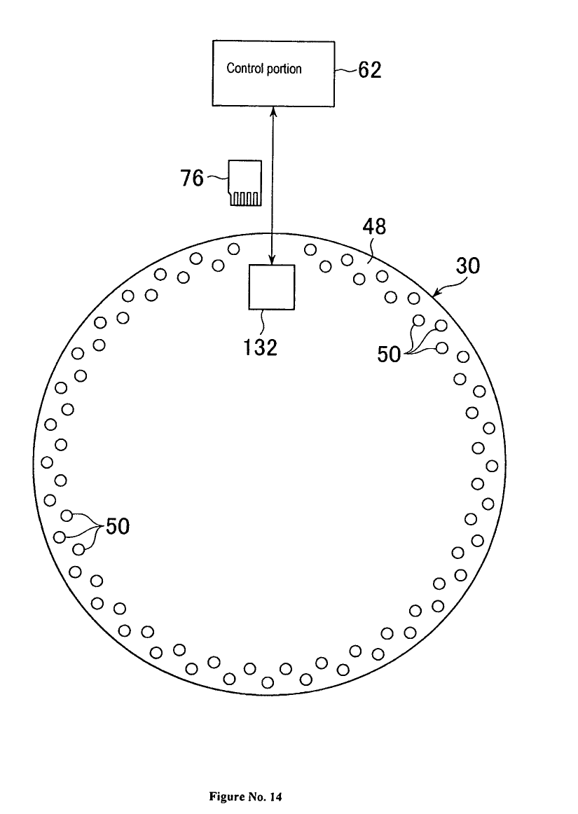

Also, as shown in FIG. 14, the memory 76 may be a removable memory such as a flexible disk, a magnetic card, a CD, an IC card or the like. In this case, a location 132 of the memory 76 is provided on the wiring base plate 48 of the probe card 30, and the information in the memory 76 is manually transferred from the probe card 30 to the memory portion 62a of the control portion 62 or vice versa.

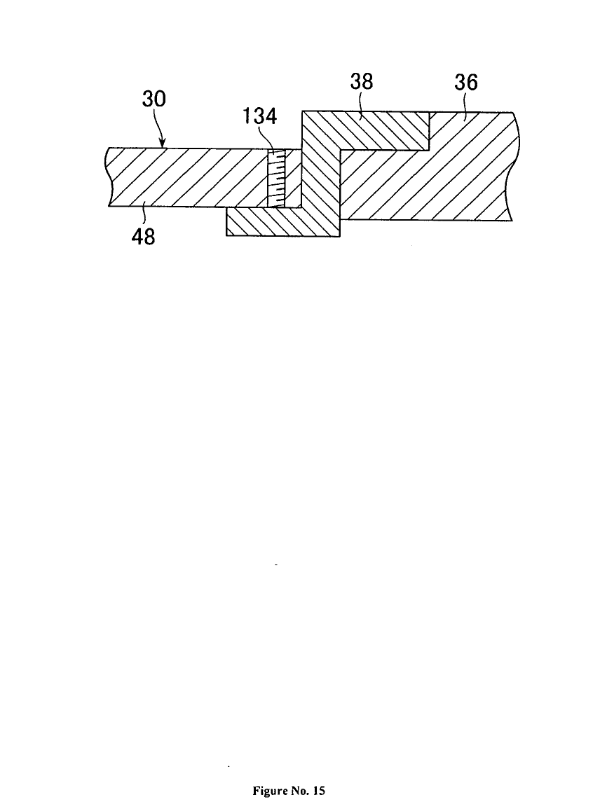

As shown in FIG. 15, the parallelism of the probe card 30 to the reference plane preset in the probing apparatus 10, in particular, the parallelism of the probe face may be adjusted by another member such as a plurality of adjusting screws 134 screwed into the screw holes of the wiring base plate 48 of the probe card 30 and abutting the lower inner periphery of the card holder 38 and a plurality of adjusting screws (not shown) screwed into the screw holes on the upper outer periphery of the card holder 38 and abutting the stage portion 42 of the card table 26.

The above-mentioned adjustment of parallelism can be performed after adjusting the screwing amount of the adjusting screws 134 into the card holder 24 (or the support member 36) by loosening attaching screws (not shown) for attaching the probe card 30 (or the card holder 38) to the card holder 38 (or the support member 36) and tightening the attaching screws.

The above-mentioned adjustment of parallelism can be performed by operating the attaching screws and the adjusting screws 134. Thus, at least the card table 26 and the adjusting screws 134 act as displacing mechanisms for adjusting an inclination angle of the probe card 30 to the probing apparatus 10.

It is possible, however, to adjust the inclination angle of the probe card 30 to the probing apparatus 10 by attaching the probe card 30 to the card table 26 through an angle adjustment stage and driving the angle adjustment stage by means of a motor and inclining the probe card 30.

Concrete adjustment of the parallelism of the probe face and the reference plane may be conducted by another known method. Also, adjustment of two-dimensional tip positions may not necessarily be made.

The present invention is not limited to the above embodiments but can be variously changed without departing from its purport.

What is claimed:

1. A probing apparatus comprising:
an inspection stage for receiving a flat plate-like device under test with a plurality of electrodes and moving the device under test on said stage in at least three directions of an X direction, a Y direction which intersect each other within a parallel plane to the device under test and a Z direction intersecting both the directions;
a probe card having a plurality of probes and supported at intervals from said inspection stage to the Z direction such that the tips of said probes face said inspection stage;
a displacing mechanism for relatively displacing said probe card and said inspection stage for adjustment of parallelism of the device under test on said inspection stage and said probe card;
a plurality of measuring instruments each for measuring an interval between said inspection stage and said probe card and arranged in either one of said inspection stage and said probe card at intervals in the X direction and the Y direction; and
a memory portion for storing the intervals measured by each of said measuring instruments.

2. The probing apparatus claimed in claim 1, wherein said memory portion stores each of said measured data in a state that the probe face of said probe card and a reference plane of said device under test are parallel.

3. The probing apparatus claimed in claim 2, wherein said probe face is an imaginary plane representing a height position of said probe tips.

4. The probing apparatus claimed in claim 2, wherein said reference plane is an imaginary plane formed by the surface of said device under test or an electrode group provided on the surface.

5. The probing apparatus claimed in claim 1, wherein each measuring instrument includes a laser length measuring instrument using a laser beam.

6. The probing apparatus claimed in claim 1 or 5, further comprising a plurality of targets individually corresponding to said measuring instruments and to be used for measurement of the intervals by the corresponding measuring instruments, said plurality of targets are arranged on the other of said inspection stage and said probe card.

7. A probing apparatus comprising: an inspection stage for receiving a flat plate-like device under test having a plurality of electrodes and for moving said device under test on said stage in at least three directions of an X direction and a Y direction intersecting each other within a parallel plane to said device under test and in a Z direction intersecting both the directions; and
a probe card having a plurality of probes provided on a base plate and on one face of said base plate and arranged at intervals from said inspection stage in the Z direction such that the tips of said probes face said inspection stage,
wherein said base plate of said probe card disposes a memory storing information at least on said probes of said device under test.

8. The probing apparatus claimed in claim 7, further comprising a card table spaced apart from said inspection stage in the Z direction, said card table having a hole penetrating in its thickness direction and supporting said probe card;
wherein said memory has a plurality of terminals for recording and reading information;
wherein said probe card has a plurality of wirings connected to the terminals of said memory; and
wherein said card table has a plurality of first contact pins electrically connected to said wirings of the probe card disposed thereon, and a plurality of second contact pins connected to said first contact pins.

9. The probing apparatus claimed in claim 7, further comprising: a stage table for supporting said inspection stage; a card table spaced part from said inspection stage in the Z direction, said card table having a hole penetrating in its thickness direction and supporting said probe card; and a displacing mechanism for relatively displacing said probe card and said inspection stage so as to adjust the parallelism of the device under test received on said inspection stage and said probe card;
wherein said memory has a plurality of terminals for recording and reading information;
wherein said probe card has a first infrared communication apparatus connected to the terminals of said memory;
wherein said card table includes a support member supported on said stage table by said displacing mechanism, a ring-like card holder supported on said support member so as to penetrate said support member, said card holder supporting said probe card such that the tips of said probes face said inspection stage;
wherein said card holder has a space which permits the infrared transmitted from said first infrared communication apparatus disposed thereon to pass; and
wherein said support member has a second infrared communication apparatus for receiving the infrared transmitted from said first infrared communication apparatus through said space.

10. The probing apparatus claimed in claim 7, wherein said memory includes a data carrier capable of reading the information stored therein by use of an electromagnetic wave.

11. The probing apparatus claimed in claim 7, wherein said memory includes a removable disk removably disposed on said base plate.
